(19) United States
(12) Patent Application Publication
(10) Pub. No.: US 2024/0128350 A1
(43) Pub. Date: Apr. 18, 2024

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Seiji NOGUCHI, Matsumoto-city (JP)

(73) Assignee: FUJI ELECTRIC CO., LTD., Kawasaki-shi (JP)

(21) Appl. No.: 18/475,041

(22) Filed: Sep. 26, 2023

(30) Foreign Application Priority Data
Oct. 17, 2022 (JP) 2022-166485

(51) Int. Cl. H01L 29/66; H01L 29/423; H01L 29/739

(52) U.S. Cl. CPC H01L 29/66348; H01L 29/4236; H01L 29/7397

(57) ABSTRACT

A method of manufacturing a semiconductor device, including: preparing a semiconductor substrate; forming a first semiconductor layer at a first main surface of the semiconductor substrate; forming and etching an oxide film to form a trench mask; using the trench mask to form a plurality of trenches penetrating through the first semiconductor layer; forming a plurality of gate insulating films along the surface of the first semiconductor layer and bottoms and sidewalls of the plurality of trenches; forming a polycrystalline silicon layer on the plurality of gate insulating films; etching the polycrystalline silicon layer to form a plurality of gate electrodes; selectively forming a plurality of first semiconductor regions in the first semiconductor layer; forming a first electrode at the surface of the first semiconductor layer and on the plurality of first semiconductor regions; and forming a second electrode at a second main surface of the semiconductor substrate.

### CROSS REFERENCE TO RELATED APPLICATIONS

This application is based upon and claims the benefit of priority of the prior Japanese Patent Application No. 2022-166485, filed on Oct. 17, 2022, the entire contents of which are incorporated herein by reference.

### BACKGROUND OF THE INVENTION

### 1. Field of the Invention

Embodiments of the invention relate to a semiconductor device and method of manufacturing a semiconductor device.

### 2. Description of the Related Art

Power semiconductor devices include various types such as bipolar transistors, insulated gate bipolar transistors (IGBTs), and metal oxide semiconductor field effect transistors (MOSFETs), used according to purpose.

For example, while bipolar transistors and IGBTs have a high current density and enable large currents as compared to MOSFETs, bipolar transistors and IGBTs cannot be switched at high speeds. In particular, use of a bipolar transistor has a switching frequency limit of about several kHz while use of an IGBT has a switching frequency limit of about several tens of kHz. On the other hand, while power MOSFETs have a low current density and accommodation of large currents is difficult as compared to bipolar transistors and IGBTs, power MOSFETs may be operated at high switching speeds of about several MHz.

A planar gate structure is a MOS gate structure in which MOS gates are provided in a plate-like shape on a front surface of a semiconductor substrate. A trench gate structure is a MOS gate structure in which MOS gates are embedded in trenches formed in a semiconductor substrate (semiconductor chip) at a front surface thereof and a channel (inversion layer) is formed along sidewalls of the trenches in a direction orthogonal to the front surface of the semiconductor substrate. Thus, as compared to a planar gate structure in which a channel is formed along the front surface of the semiconductor substrate, unit cell (constituent unit of a device) density per unit area may be increased and current density per unit area may be increased, which are advantageous in terms of cost.

FIG. 12 is a flowchart of trench structure formation by a method of manufacturing a conventional semiconductor device. FIGS. 13, 14, 15, 16, 17, 18, 19, and 20 are cross-sectional views depicting states during formation of a trench structure by a method of manufacturing a conventional semiconductor device. A method of forming a gate trench (trench structure) in a conventional semiconductor device is described with reference to the figures.

First, as depicted in FIG. 13, a thermal oxide film (SiO₂) 123 is grown on a surface of a semiconductor starting substrate 144 (step S11). In the semiconductor starting substrate 144, for example, front device structures such as a p-type base region, an n-type accumulating layer, etc. are formed in an n⁻-type semiconductor starting substrate.

Next, as depicted in FIG. 14, the thermal oxide film 123 is etched, whereby a trench mask 127 having openings of a predetermined width is formed (step S12). Next, as depicted in FIG. 15, silicon (Si) is etched by dry etching, thereby forming gate trenches 146 (step S13). Next, as depicted in FIG. 16, the entire trench mask 127 is removed (step S14).

Next, as depicted in FIG. 17, a gate insulating film 108 is formed along a front surface of the semiconductor starting substrate 144 and a bottom and sidewalls of each of the gate trenches 146 (step S15). Next, as depicted in FIG. 18, on the gate insulating film 108, a polycrystalline silicon layer (polysilicon) 126 doped with, for example, phosphorus atoms is formed (step S16). The polycrystalline silicon layer 126 is formed so as to be embedded in the gate trenches 146.

Next, as depicted in FIG. 19, the polycrystalline silicon layer 126 is etched and left in the gate trenches 14, thereby forming the gate electrodes s 110 (step S17). In this etching, the polycrystalline silicon layer 126 at the surface of mesas is completely etched until the gate insulating film 108 is exposed. A mesa may be a region sandwiched between any adjacent two of the gate trenches 146. Next, as depicted in FIG. 20, on the surface of the semiconductor starting substrate 144, a mask (not depicted) having predetermined openings is formed by photolithography using, for example, a resist. Subsequently, an n-type impurity is ion-implanted by an ion implantation method using the resist as a mask. As a result, in portions of the semiconductor starting substrate 144 at the front surface thereof, an n⁺-type emitter region 112 is formed (step S18). Thus, the trench structure is formed.

Further, according to a known technique, a mixed gas containing at least any one of a chlorine-based gas and a bromine-based gas, and oxygen gas is introduced into a single-wafer dry etching device and a polysilicon layer is removed by etch-back, whereby an upper surface depression depth of a polysilicon plug when the polysilicon layer is etched back is minimized (for example, refer to Japanese Laid-Open Patent Publication No. H7-130711).

### SUMMARY OF THE INVENTION

According to an embodiment of the invention, a semiconductor device includes a semiconductor substrate of a first conductivity type, the semiconductor substrate having a first main surface and a second main surface opposite to each other; a first semiconductor layer of a second conductivity type, provided at the first main surface of the semiconductor substrate, the first semiconductor layer having a first surface and a second surface opposite to each other, the second surface facing the semiconductor substrate; a plurality of first semiconductor regions of the first conductivity type, selectively provided in the first semiconductor layer, at the first surface of the first semiconductor layer; a plurality of trenches penetrating through the plurality of first semiconductor regions and the first semiconductor layer and reaching the semiconductor substrate; a plurality of gate electrodes provided in the plurality of trenches, via a plurality of gate insulating films, respectively; a first electrode provided at the first surface of the first semiconductor layer and on the plurality of first semiconductor regions; and a second electrode provided at the second main surface of the semiconductor substrate. Each of the plurality of first semiconductor regions has a surface facing the first electrode. Each of the plurality of gate electrodes has a surface facing the first electrode. In a depth direction of the semiconductor device, a distance between the surface of any one of the plurality of first semiconductor regions and the surface of one of the plurality of gate electrodes that is closest to said any one of the plurality of first semiconductor regions is in a range of 0.1 μm to 0.3 μm.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a semiconductor device according to an embodiment.

FIG. 2 is a flowchart of trench structure formation by a method of manufacturing the semiconductor device according to the embodiment.

FIG. 3 is a cross-sectional view depicting a state during formation of a trench structure by the method of manufacturing the semiconductor device according to the embodiment.

FIG. 4 is a cross-sectional view depicting a state during formation of a trench structure by the method of manufacturing the semiconductor device according to the embodiment.

FIG. 5 is a cross-sectional view depicting a state during formation of a trench structure by the method of manufacturing the semiconductor device according to the embodiment.

FIG. 6 is a cross-sectional view depicting a state during formation of a trench structure by the method of manufacturing the semiconductor device according to the embodiment.

FIG. 7 is a cross-sectional view depicting a state during formation of a trench structure by the method of manufacturing the semiconductor device according to the embodiment.

FIG. 8 is a cross-sectional view depicting a state during formation of a trench structure by the method of manufacturing the semiconductor device according to the embodiment.

FIG. 9 is a cross-sectional view depicting a state during formation of a trench structure by the method of manufacturing the semiconductor device according to the embodiment.

FIG. 10 is a cross-sectional view depicting a state during formation of a trench structure by the method of manufacturing the semiconductor device according to the embodiment.

FIG. 11 is a cross-sectional view depicting a state during formation of a trench structure by the method of manufacturing the semiconductor device according to the embodiment.

FIG. 12 is a flowchart of trench structure formation by a method of manufacturing a conventional semiconductor device.

FIG. 13 is a cross-sectional view depicting a state during formation of a trench structure by a method of manufacturing a conventional semiconductor device.

FIG. 14 is a cross-sectional view depicting a state during formation of the trench structure by the method of manufacturing the conventional semiconductor device.

FIG. 15 is a cross-sectional view depicting a state during formation of the trench structure by the method of manufacturing the conventional semiconductor device.

FIG. 16 is a cross-sectional view depicting a state during formation of the trench structure by the method of manufacturing the conventional semiconductor device.

FIG. 17 is a cross-sectional view depicting a state during formation of the trench structure by the method of manufacturing the conventional semiconductor device.

FIG. 18 is a cross-sectional view depicting a state during formation of the trench structure by the method of manufacturing the conventional semiconductor device.

FIG. 19 is a cross-sectional view depicting a state during formation of the trench structure by the method of manufacturing the conventional semiconductor device.

FIG. 20 is a cross-sectional view depicting a state during formation of the trench structure by the method of manufacturing the conventional semiconductor device.

### DETAILED DESCRIPTION OF THE INVENTION

First, problems associated with the conventional techniques are discussed. As described above, in the trench mask removal process (step S14), the trench mask 127 used as a hardmask during the Si etching of the front surface (mesa surface) of the semiconductor starting substrate 144 is completely removed between the gate trenches 146 and the Si surface is in a state in which Si is exposed.

By a process of performing gate oxidation from this state and forming the gate insulating film 108 of a thickness of about 0.1 μm and the polycrystalline silicon layer 126, polycrystalline silicon is grown to have a thickness of about 0.8 μm. Thereafter, the polycrystalline silicon layer 126 is etched by an etching process, however, at this time, the polycrystalline silicon layer 126 deposited at the mesa surface is completely etched, whereby a base oxide film (the gate insulating film 108) is exposed. At this time, the polycrystalline silicon layer 126 embedded in the gate trench 146 is also concurrently etched and thus, the polycrystalline silicon layer 126 drops below the Si surface. The amount of drop is greatest in a center and smallest at a region in contact with the gate insulating film 108 at a sidewall of the gate trench 146. A distance h3 between the front surface (the Si surface) of the semiconductor starting substrate 144 and a portion of the polycrystalline silicon layer 126 where the drop is smallest reaches about 0.3 μm to 0.5 μm from the Si surface (refer to FIG. 20).

Here, to improve characteristics, accompanying miniaturization of the gate trench 146 structure of a trench IGBT or a trench MOSFET, a diffusion depth of the n⁺-type emitter region 112 and an n⁺-type source region forming the gate trench 146 structure has to be formed shallowly. In this case, as depicted in FIG. 20, with the conventional technique described above, the distance h3 of the polycrystalline silicon layer 126 in the gate trench 146 becomes deeper than the n⁺-type emitter region 112 and/or greater than a thickness of the n⁺-type source region, whereby the n⁺-type emitter region 112 and the n⁺-type source region are apart from (are not in contact with) the gate electrodes 110 (the polycrystalline silicon layer 126). In this case, a problem arises in that the IGBT (the MOSFET) stops operating and thus, there is a limit to the miniaturization.

Further, as a method to solve the problem described above, etching the entire polycrystalline silicon layer 126 at the surface by a chemical mechanical polishing (CMP) technique is generally known. Nonetheless, with the CMP technique, the polycrystalline silicon layer 126 on the surface is completely etched and thus, in a region of an active region excluding the trench gate structure portion, when it is desirable to form the polycrystalline silicon layer 126 in a region at the surface, the polycrystalline silicon layer 126 has to again be formed, leading to a problem of increased wafer processing costs. Furthermore, the application of CMP technology itself has a problem in that wafer processing costs are higher as compared to conventionally etching the polycrystalline silicon layer 126.

Embodiments of a semiconductor device and a method of manufacturing a semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical will be given the same reference numerals and are not repeatedly described. Further, in the present description, when Miller indices are described, “−” means a bar added to an index immediately after the “−”, and a negative index is expressed by prefixing “−” to the index. Further, with consideration of variation in manufacturing, description indicating the same or equal may be within 5%.

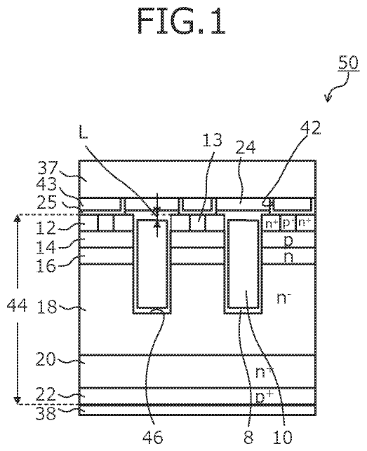

A structure of a semiconductor device according to an embodiment is described taking an IGBT as an example. FIG. 1 is a cross-sectional view depicting the structure of the semiconductor device according to the embodiment. In FIG. 1, only an active region through which current flows during an on-state is depicted while an edge termination region that surrounds a periphery of the active region in substantially a rectangular shape and in which a voltage withstanding structure is provided is not depicted. The voltage withstanding structure has a function of mitigating electric field close to a border between the active region and the edge termination region and sustaining a breakdown voltage. The breakdown voltage is a voltage limit at which, even when current between a drain and source increases due to avalanche breakdown at a pn junction, the current between the drain and source does not increase more than this.

An IGBT 50 may have an n-type accumulating layer 16 provided in an n⁻-type semiconductor starting substrate (semiconductor substrate of a first conductivity type) 18, at a front surface of the n⁻-type semiconductor starting substrate 18 constituting an n⁻-type drift layer. The n-type accumulating layer 16 is a so-called current spreading layer (CSL) that reduces carrier spreading resistance. On the n-type accumulating layer 16 (at a front surface of the n⁻-type semiconductor starting substrate 18), a p-type base region (first semiconductor layer of a second conductivity type) 14 is provided. Gate trenches 46 that penetrate through the p-type base region 14 and reach the n⁻-type semiconductor starting substrate 18 are provided. At both sides of each of the gate trenches 46, n⁺-type emitter regions (first semiconductor regions of the first conductivity type) 12 are provided, disposed at predetermined intervals, for example, in a striped layout in a plan view of the device, separating the p-type base region 14 into multiple regions (mesa portions). In the gate trenches 46, gate insulating films 8 are provided along inner walls of the gate trenches 46 and gate electrodes 10 are provided on the gate insulating films 8, respectively.

In the p-type base region 14, at each of the mesa portions, the n⁺-type emitter regions 12 and p⁺-type contact regions 13 are each selectively provided. The n⁺-type emitter regions 12 face the gate electrodes 10 with the gate insulating films 8 provided at the inner walls of the gate trenches 46 intervening therebetween. The n⁺-type emitter regions 12 are provided closer to the gate trenches 46 than are the p⁺-type contact regions 13. The p⁺-type contact regions 13 may be omitted. In an instance in which the p⁺-type contact regions 13 are omitted, at locations farther apart from the gate trenches 46 than are the n⁺-type emitter regions 12, the p-type base region 14 reaches a front surface of a semiconductor substrate 44 and is exposed at the front surface of the semiconductor substrate 44.

A front electrode (first electrode) 37 is in contact with the n⁺-type emitter regions 12 via contact holes 42 and is electrically insulated from the gate electrodes 10 by an interlayer insulating film 24. Openings may be selectively provided in the n⁺-type emitter regions 12, and in the openings, the front electrode 37 and the p-type base region 14 may be electrically connected. The front electrode 37 functions as an emitter electrode.

In the n⁻-type semiconductor starting substrate 18, close to a back surface thereof, an n⁺-type field stop FS layer 20 may be provided. The n⁺-type FS layer 20 has a function of suppressing the spreading of a depletion layer from a pn junction between the p-type base region 14 and the n⁻-type semiconductor starting substrate 18 to a later-described p⁺-type collector region 22 during an off-state.

In the n⁻-type semiconductor starting substrate 18, at a position shallower from the back surface thereof than is the n⁺-type FS layer 20, the p⁺-type collector region 22 is provided, and a back electrode (second electrode) 38 is provided at a surface (entire area of back surface of the n⁻-type semiconductor starting substrate 18) of the p⁺-type collector region 22. The back electrode 38 functions as a collector electrode. The p⁺-type collector region 22, the n⁻-type semiconductor starting substrate 18, the n⁺-type FS layer 20, the n-type accumulating layer 16, and the p-type base region 14 collectively are referred to as the semiconductor substrate 44.

Further, in the contact holes 42, at the bottom and side surfaces of each, a barrier metal 25 containing titanium (Ti), titanium nitride (TiN), tantalum (Ta), tantalum nitride (TaN), etc. or stacked layers thereof may be formed. Further, to favorably connect the front electrode 37 with the n⁺-type emitter regions 12 and the p⁺-type contact regions 13, the contact holes 42 may form metal plugs 43 containing tungsten (W), molybdenum (Mo), etc.

In the embodiment, the gate electrodes 10 drop below the surfaces of the n⁺-type emitter regions 12. In FIG. 1, while not depicted, the amount of drop is greatest in a center and smallest in regions in contact with the gate insulating films 8 at the sidewalls of the gate trenches 46 (refer to FIG. 8). In the embodiment, each of the n⁺-type emitter regions 12 has a front surface facing the front electrode 37, each of the gate electrodes 10 has a front surface facing the front electrode 37, and a distance L between the front surface of any one of the n⁺-type emitter regions 12 and the front surface of a closest one of the gate electrodes 10, the closest one being closest to the front surface of the any one of the n⁺-type emitter regions 12, is in a range of 0.1 μm to 0.3 μm. The distance L may be a height in a thickness direction. The front surface of the gate electrode 10 closest to the front surface of the any one of the n⁺-type emitter regions 12 is a surface thereof where the drop is smallest.

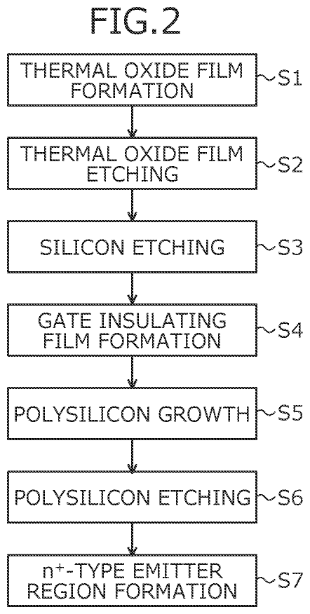

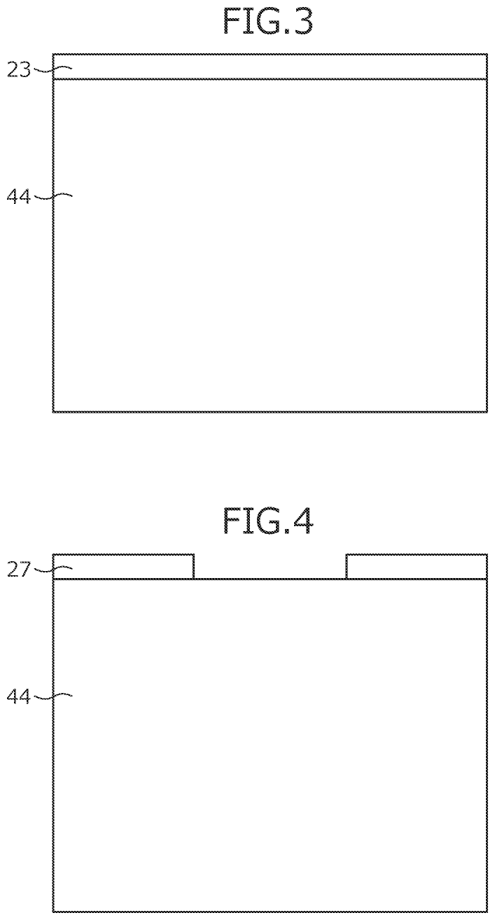

Next, a method of manufacturing the semiconductor device according to the embodiment is described. FIG. 2 is a flowchart of trench structure formation by the method of manufacturing the semiconductor device according to the embodiment. FIGS. 3, 4, 5, 6, 7, 8, 9, 10, and 11 are cross-sectional views depicting states during formation of the trench structure by the method of manufacturing the semiconductor device according to the embodiment. Here, formation of the trench structure of the IGBT 50 depicted in FIG. 1 is mainly described.

First, for example, in the n⁻-type semiconductor starting substrate (semiconductor wafer) 18 containing silicon, front device structures such as a MOS gate portion of the trench gate type IGBT 50 are formed at the front surface of the n⁻-type semiconductor starting substrate 18. For example, the front device structures are formed as follows. First, the n⁻-type semiconductor starting substrate 18 that constitutes an n⁻-type drift region is prepared. Next, on the front surface of the n⁻-type semiconductor starting substrate 18, an ion implantation mask having a predetermined opening is formed by photolithography (not depicted) using, for example, a photoresist. The opening is formed at a position where the n-type accumulating layer 16 is to be provided. Ion implantation of an n-type impurity such as, for example, phosphorus (P), arsenic (As), etc. is performed using the mask as an ion implantation mask. By this ion implantation, the n-type accumulating layer 16 in which an n-type impurity is implanted is formed in the n⁻-type semiconductor starting substrate 18.

Next, on the front surface of the n⁻-type semiconductor starting substrate 18, an ion implantation mask (not depicted) having a predetermined opening is formed by photolithography using, for example, a photoresist. The opening is formed at a position where the p-type base region 14 is to be provided. Ion implantation of a p-type impurity such as, for example, boron (B) is performed using the mask as an ion implantation mask. By this ion implantation, the p-type base region 14 ion-implanted with a p-type impurity is formed in the n⁻-type semiconductor starting substrate 18, at the front surface of the n⁻-type semiconductor starting substrate 18 (first process).

Next, as depicted in FIG. 3, a thermal oxide film (SiO₂) 23 is grown on the surface of the semiconductor substrate 44 (step S1: second process). The semiconductor substrate 44 in FIGS. 3, 4, 5, 6, 7, 8, 9, 10, and 11 is formed by forming front device structures such as the p-type base region 14, the n-type accumulating layer 16, etc. in the n⁻-type semiconductor starting substrate 18.

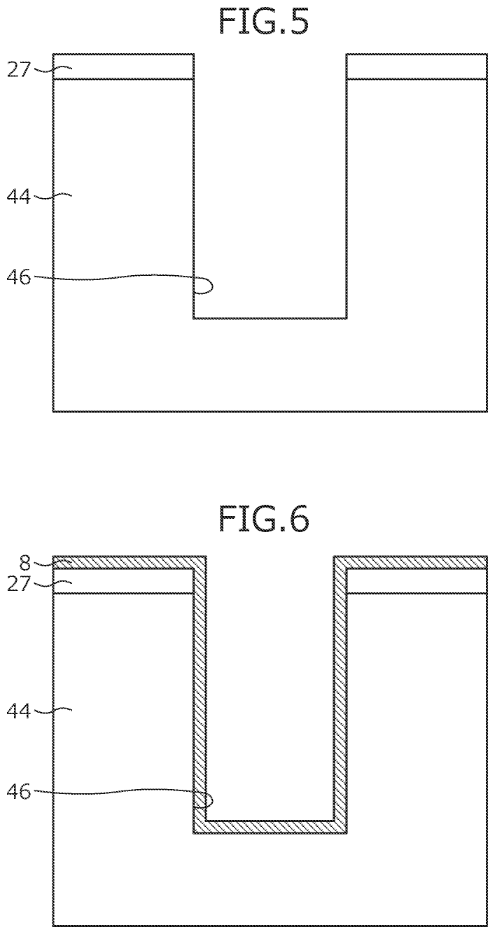

Next, as depicted in FIG. 4, the thermal oxide film 23 is etched, thereby forming a trench mask 27 having predetermined openings (step S2: third process). The trench mask 27 may be formed by growing a nitride film, for example, a silicon nitride film (Si₃N₄) and performing photolithography so that the trench mask 27 has openings of a predetermined width. The nitride film has a smaller etching rate than does the thermal oxide film 23 and therefore, may obtain the same effect with a thinner thickness than that of the thermal oxide film 23. Next, as depicted in FIG. 5, silicon is etched by dry etching using the trench mask 27 as a mask, thereby forming the gate trenches 46 that penetrate through the p-type base region 14 and reach the n⁻-type semiconductor starting substrate 18 (step S3: fourth process).

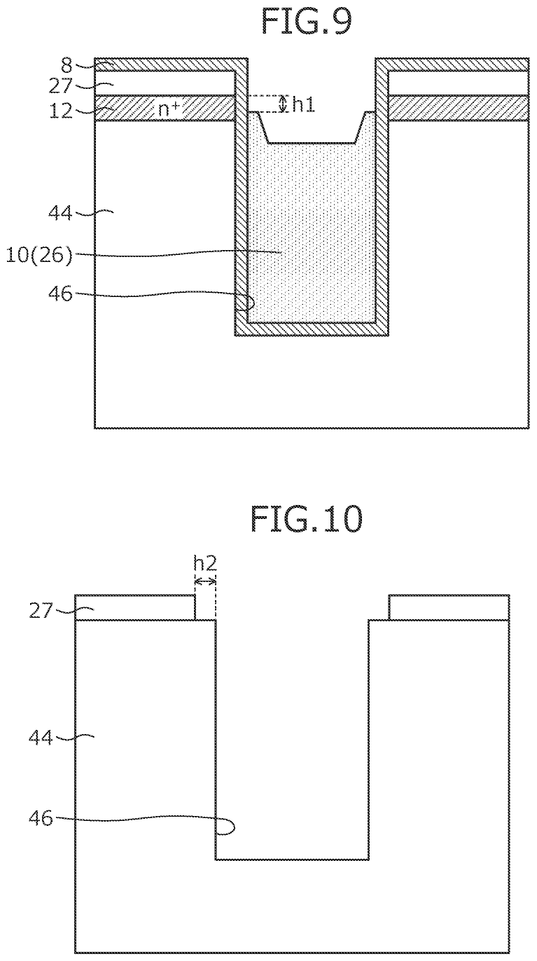

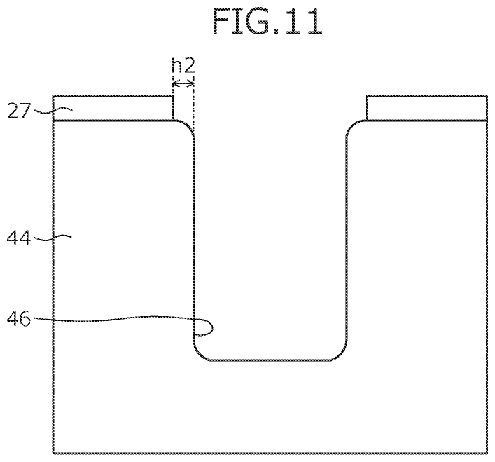

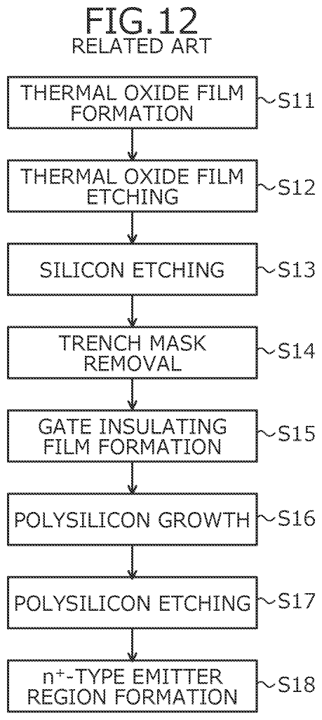

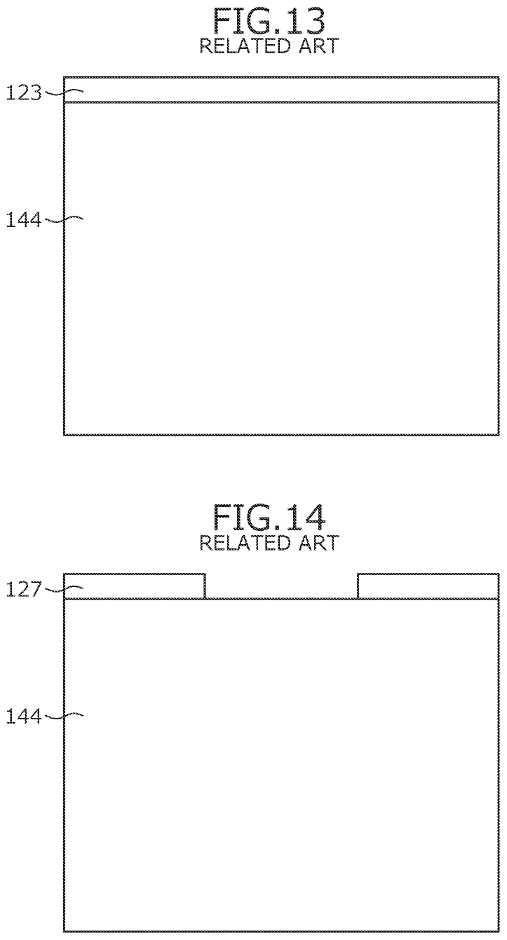

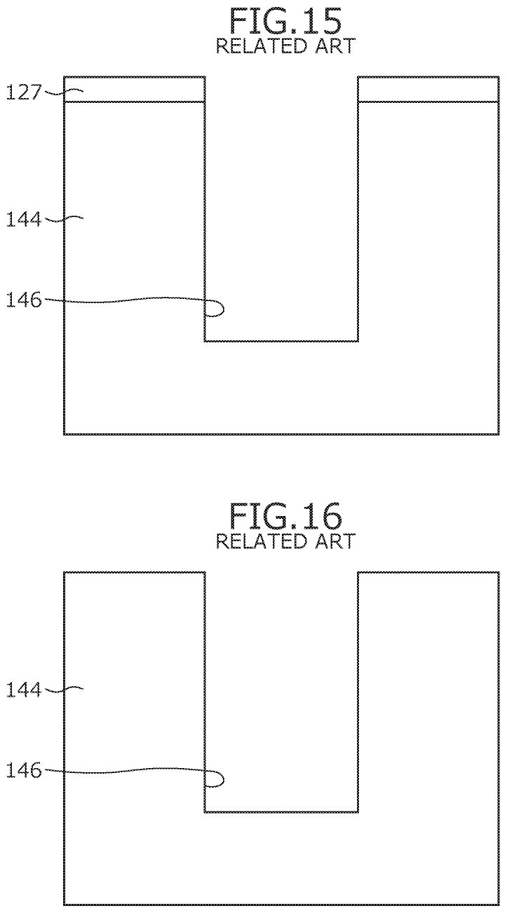

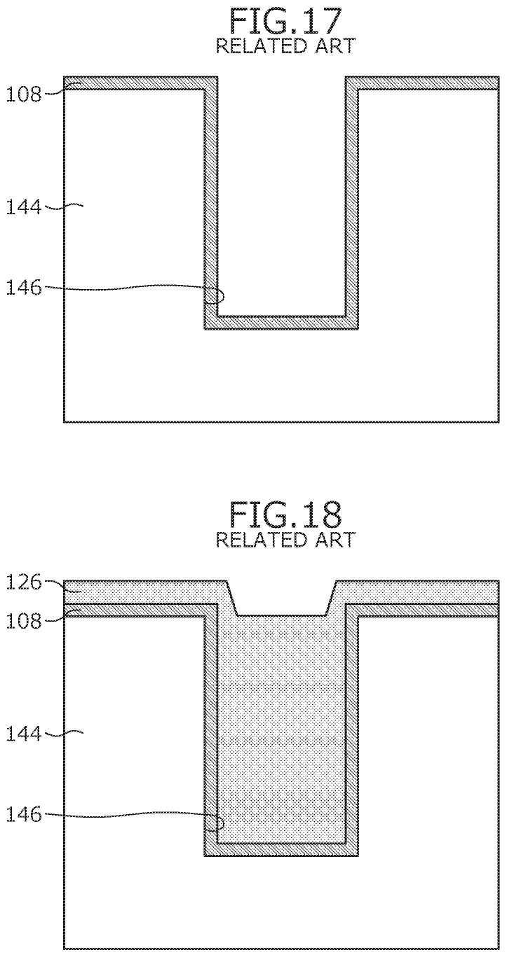

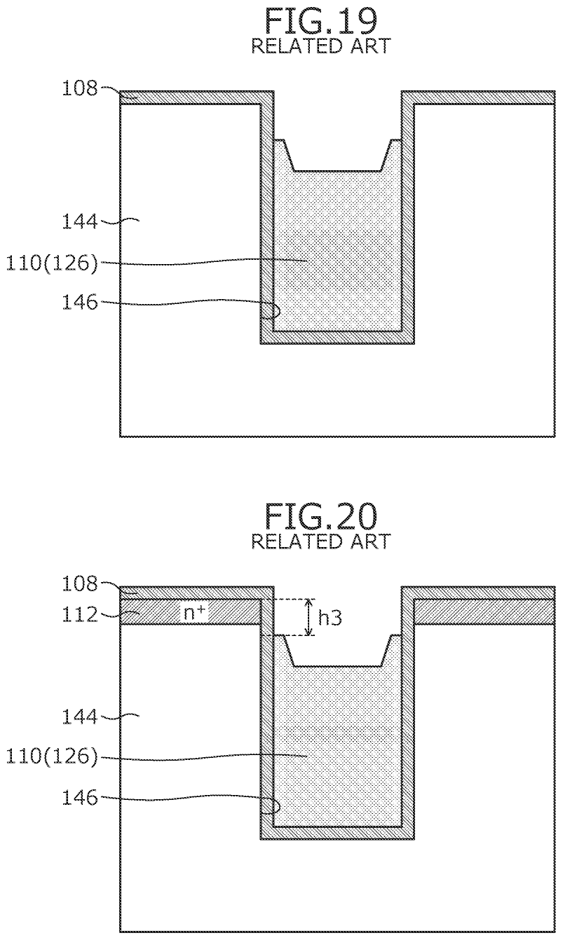

After the gate trenches 46 are formed, at the openings of the gate trenches 46, portions of the trench mask 27 having a width h2 from the openings of the gate trenches 46 may be removed as depicted in FIG. 10, and isotropic etching for removing damage of the gate trenches 46 and sacrificial oxidation for rounding corners of the openings of the gate trenches 46 and the bottoms of the gate trenches 46 may be performed. The width h2 is, for example, in a range of 0.1 μm to 0.15 μm. FIG. 11 depicts the gate trenches 46 after rounding of the corners of the openings and the bottoms. The isotropic etching or the sacrificial oxidation alone may be performed. Further, after the isotropic etching is performed, the sacrificial oxidation may be performed. As a result, a clean surface of silicon may be produced and by rounding the corners, electric field concentration at the bottoms and openings of the gate trenches 46 may be suppressed.

Next, as depicted in FIG. 6, in the embodiment, the trench mask 27 is left as is and along the surface of the semiconductor substrate 44 and the bottoms and the sidewalls of the gate trenches 46, the gate insulating films 8 are formed (step S4: fifth process). The gate insulating films 8 may be formed by thermal oxidation. The gate insulating films 8 may be formed by a CVD method.

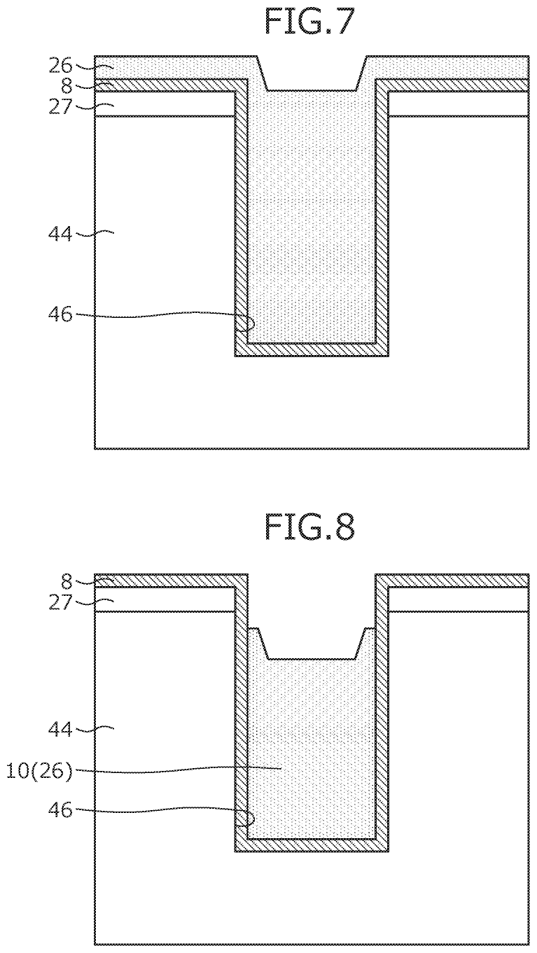

Next, as depicted in FIG. 7, on the gate insulating films 8, for example, a polycrystalline silicon layer (polysilicon) 26 doped with phosphorus atoms is formed (step S5: sixth process). The polycrystalline silicon layer 26 is formed so as to be embedded in the gate trenches 46. The polycrystalline silicon layer 26 may be formed by a CVD method.

Next, as depicted in FIG. 8, the polycrystalline silicon layer 26 is etched and left in the gate trenches 46, whereby the gate electrodes 10 are formed (step S6: seventh process). In the etching, the polycrystalline silicon layer 26 at mesa surfaces is completely etched until the trench mask 27 is exposed. At this time, the polycrystalline silicon layer 26 embedded in the gate trenches 46 is also concurrently etched and thus, the polycrystalline silicon layer 26 drops below the Si surface. The amount of drop is greatest at the center and smallest at a region in contact with the gate insulating films 8 at the sidewalls of the gate trenches 46.

Next, as depicted in FIG. 9, on the surface of the semiconductor substrate 44, an ion implantation mask having predetermined openings is formed by photolithography (not depicted), for example, using a photoresist. The openings are formed at positions where the n⁺-type emitter regions 12 are to be provided in the p-type base region 14. Ion implantation of an n-type impurity, for example, phosphorus (P), arsenic (As), etc. is performed using the ion implantation mask as a mask. By this ion implantation, the n⁺-type emitter regions 12 implanted with an n-type impurity are formed in the p-type base region 14, at the surface of the p-type base region 14 (step S7: eighth process).

As described, in the embodiment, after the gate trenches 46 are formed, the trench mask 27 constituting a hardmask at the surface (mesa surface) of portions of the semiconductor substrate 44 between the gate trenches 46 during trench etching is entirely or partially left, and in this state, the process of forming the gate insulating films 8 and subsequent processes are performed.

When the silicon is etched at step S3, the trench mask 27 used as a hardmask is etched according to a selection ratio. For example, under etching conditions, before the silicon is etched, the trench mask 27 is 0.4 μm and after the etching is about 0.2 μm. The surface of the trench mask 27 is contaminated with heavy metals and therefore, before the gate insulating films 8 are formed, the surface may be removed by light etching so that the thickness is in a range of about 0.1 μm to 0.15 μm.

When the trench mask 27 is left as in the present embodiment, the thickness (0.3 μm) of the base oxide film constituting the trench mask 27 and the gate insulating films 8 of the mesa surfaces is thicker than that of the conventional gate insulating films 8 (0.1 μm) and even if the amount of drop of the polycrystalline silicon layer 26 after the polycrystalline silicon layer 26 is etched does not change, the amount of drop from the semiconductor substrate 44 surface may be reduced.

For example, when the thickness of the base oxide film at the mesa surfaces is 0.3 μm, a distance h1 (about 0.3 μm to 0.5 μm in the prior art) from the semiconductor substrate 44 surface (the Si surface) to a portion of the polycrystalline silicon layer 26 where the drop is smallest may be decreased to a range of about 0.1 μm to 0.3 μm from the Si surface (refer to FIG. 9). Thus, even when the depth of the n⁺-type emitter regions 12 of a trench IGBT or the n⁺-type source regions of a trench MOSFET is shallow, the n⁺-type emitter regions 12 and the n⁺-type source regions are in contact with the gate electrodes 10 (the polycrystalline silicon layer 26) and may prevent failure of the IGBT or the MOSFET. As described, the amount of drop of the polycrystalline silicon layer 26 may be reduced and thus, even without application of a CMP technology, depths of the n⁺-type emitter regions 12 of the trench IGBT and the n⁺-type source regions of the trench MOSFET may be shallow.

Next, on the surface of the n⁻-type semiconductor starting substrate 18, an ion implantation mask having predetermined openings is formed by photolithography (not depicted) using, for example, a photoresist. The openings are formed at positions where the p⁺-type contact regions 13 are to be formed in the p-type base region 14. Ion implantation of a p-type impurity such as, for example, B is performed using the ion implantation mask as a mask. By this ion implantation, in the p-type base region 14, at the surface thereof, the p⁺-type contact regions 13 implanted with a p-type impurity are formed.

Next, a heat treatment (activation annealing) for activating the p-type base region 14, the n-type accumulating layer 16, the n⁺-type emitter regions 12, and the p⁺-type contact regions 13 formed by ion implantation is performed. For example, a heat treatment (annealing) is performed under an inert gas atmosphere of about 1000 degrees C. As described, the activation annealing may be performed for the ion implanted regions collectively or may be performed each time ion implantation is performed.

Next, the interlayer insulating film 24 is formed in an entire area of the front surface of the n⁻-type semiconductor starting substrate 18 so as to cover the gate electrodes 10 of the trench gate type IGBT 50. The interlayer insulating film 24 may be formed by, for example, forming a HTO film and depositing BPSG on the HTO film. The HTO film and the BPSG may be formed by a CVD method. Next, by a heat treatment (reflow), chemical mechanical polishing (CMP), etc., the interlayer insulating film 24 may be planarized and coverage (step coverage) of the front electrode may be enhanced. Next, patterning including photoresist application, exposure, and a development process is performed on the interlayer insulating film 24 and a resist film having openings in predetermined regions is formed.

The resist film has openings in portions corresponding to formation regions of the contact holes 42 in the trench gate type IGBT 50. Next, dry etching is performed using the resist film as a mask and the interlayer insulating film 24 is selectively removed. In portions of the resist film exposed by the dry etching, the contact holes 42 that penetrate through the interlayer insulating film 24 in depth direction and reach the front surface of the n⁻-type semiconductor starting substrate 18 are formed.

Next, the barrier metal 25 is formed at the bottoms and sidewalls of the contact holes 42. The barrier metal 25 need not be formed on the interlayer insulating film 24. The barrier metal 25 may be formed on the interlayer insulating film 24. The barrier metal 25 may be formed by a CVD method or a sputtering method.

Next, the metal plugs 43 are formed so as to be embedded in the contact holes 42. The metal plugs 43 may contain tungsten (W). The metal plugs 43 may be formed by forming a tungsten film in an entire area of the front surface of the n⁻-type semiconductor starting substrate 18 and by performing etching back so that the metal plugs 43 are embedded in the contact holes 42.

Next, in an entire area of the front surface of the n⁻-type semiconductor starting substrate 18, the front electrode 37 that constitutes the emitter electrode is formed (ninth process). The front electrode 37 is a metal film containing, for example, aluminum (Al) as a main constituent. The front electrode 37, for example, is formed by a sputtering method. The front electrode 37 is electrically connected to the n⁺-type emitter regions 12 and the p⁺-type contact regions 13 via the metal plugs 43 and the barrier metal 25 in the contact holes 42.

Next, the n⁻-type semiconductor starting substrate 18 is ground from the back surface thereof to a position corresponding to a product thickness used for the semiconductor device. Next, from the ground back surface of the n⁻-type semiconductor starting substrate 18, phosphorus (P), selenium (Se), etc. is ion implanted thereby forming the n⁺-type FS layer 20 in the n⁻-type semiconductor starting substrate 18.

Next, from the back surface of the n⁻-type semiconductor starting substrate 18, boron (B) is ion implanted thereby forming the p⁺-type collector region 22 in the n⁻-type semiconductor starting substrate 18, the p⁺-type collector region 22 being formed at a position closer to the back surface of the n⁻-type semiconductor starting substrate 18 than is the n⁺-type FS layer 20.

Next, the impurities ion-implanted in the n⁻-type semiconductor starting substrate 18 are diffused by a heat treatment. Next, the back electrode 38 that constitutes the collector electrode is formed at the back surface of the n⁻-type semiconductor starting substrate 18 (tenth process). The back electrode 38 is a metal film containing, for example, aluminum (Al) as a main constituent. The back electrode 38, for example, is formed by a sputtering method. Thereafter, the n⁻-type semiconductor starting substrate 18 is cut into individual chips, whereby the semiconductor device depicted in FIG. 1 is completed.

As described above, according to the embodiment, the trench mask is entirely or partially left, and in this state, the process of forming the gate insulating films and subsequent processes are performed. As a result, the thickness of the base oxide film formed by the gate insulating films and the trench mask at the semiconductor substrate surface is thicker than conventionally and the amount of drop of the polycrystalline silicon layer after etching may be reduced. Thus, even when the depth of the n⁺-type emitter regions of a trench IGBT or the depth of the n⁺-type source regions of a trench MOSFET is shallow, the n⁺-type emitter regions or the n⁺-type source regions are in contact with the gate electrodes (polycrystalline silicon layer) and failure of the IGBT or the MOSFET may be prevented.

In the foregoing, while the present invention has been described taking, as an example, an instance in which a MOS gate structure is configured at a first main surface of a silicon substrate, the present invention is not limited hereto and various modifications are possible such as in the type of semiconductor (for example, silicon carbide (SiC), etc.), orientation of the substrate main surface, etc. Further, in the embodiment, while a trench-type IGBT is described as an example, without limitation hereto, application to semiconductor devices of various types of configurations such as a trench MOSFET or the like is possible. Further, in the present invention, in the embodiments, while the first conductivity type is an n-type and the second conductivity type is a p-type, the present invention is similarly implemented when the first conductivity type is a p-type and the second conductivity type is an n-type.

According to the invention described above, the trench mask is entirely or partially left, and in this state, the process of forming the gate insulating films and subsequent processes are performed. As a result, the thickness of the base oxide film formed by the gate insulating films of the semiconductor substrate surface and the trench mask is thicker than conventionally and the amount of drop of the polycrystalline silicon layer after etching may be reduced. Thus, even when the depth of the n⁺-type emitter regions (first semiconductor regions of the first conductivity type) of a trench IGBT or that of the n⁺-type source regions of a trench MOSFET is shallow, the n⁺-type emitter regions and the n⁺-type source regions are in contact with the gate electrodes (polycrystalline silicon layer) and failure of the IGBT or the MOSFET may be prevented.

The semiconductor device and the method of manufacturing a semiconductor device according to the present invention achieve an effect in that without application of a CMP technology, the amount of drop of the polycrystalline silicon layer is reduced and the depth of the n⁺-type emitter regions and that of the n⁺-type source regions may be shallow.

As described, the semiconductor device and the method of manufacturing a semiconductor device according to the present invention are useful for high-voltage semiconductor devices used in power converting equipment, power devices of various types of industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate of a first conductivity type, the semiconductor substrate having a first main surface and a second main surface opposite to each other;
a first semiconductor layer of a second conductivity type, provided at the first main surface of the semiconductor substrate, the first semiconductor layer having a first surface and a second surface opposite to each other, the second surface facing the semiconductor substrate;
a plurality of first semiconductor regions of the first conductivity type, selectively provided in the first semiconductor layer, at the first surface of the first semiconductor layer;
a plurality of trenches penetrating through the plurality of first semiconductor regions and the first semiconductor layer and reaching the semiconductor substrate;
a plurality of gate electrodes provided in the plurality of trenches, via a plurality of gate insulating films, respectively;
a first electrode provided at the first surface of the first semiconductor layer and on the plurality of first semiconductor regions; and
a second electrode provided at the second main surface of the semiconductor substrate, wherein
each of the plurality of first semiconductor regions has a surface facing the first electrode,
each of the plurality of gate electrodes has a surface facing the first electrode, and
in a depth direction of the semiconductor device, a distance between the surface of any one of the plurality of first semiconductor regions and the surface of one of the plurality of gate electrodes that is closest to said any one of the plurality of first semiconductor regions is in a range of 0.1 μm to 0.3 μm.

2. A method of manufacturing a semiconductor device, the method comprising:
preparing a semiconductor substrate of a first conductivity type, the semiconductor substrate having a first main surface and a second main surface opposite to each other;
forming a first semiconductor layer of a second conductivity type at the first main surface of the semiconductor substrate, the first semiconductor layer having a first surface and a second surface opposite to each other, the second surface facing the semiconductor substrate;
forming an oxide film at the first surface of the first semiconductor layer;
etching the oxide film, thereby forming a trench mask;
using the trench mask as a mask, thereby forming a plurality of trenches penetrating through the first semiconductor layer and reaching the semiconductor substrate;
leaving the trench mask as is and forming a plurality of gate insulating films along the first surface of the first semiconductor layer and bottoms and sidewalls of the plurality of trenches;
forming a polycrystalline silicon layer on the plurality of gate insulating films;
etching the polycrystalline silicon layer, thereby forming a plurality of gate electrodes;
selectively forming a plurality of first semiconductor regions of the first conductivity type in the first semiconductor layer, at the first surface of the first semiconductor layer;
forming a first electrode at the first surface of the first semiconductor layer and on the plurality of first semiconductor regions; and
forming a second electrode at the second main surface of the semiconductor substrate.

3. The method of manufacturing according to claim 2, wherein
each of the plurality of first semiconductor regions has a surface facing the first electrode,
each of the plurality of gate electrodes has a surface facing the first electrode, and
the etching the polycrystalline silicon layer includes forming a distance of 0.1 μm to 0.3 μm between the surface of any one of the plurality of first semiconductor regions and the surface of one of the plurality of gate electrodes that is closest to said any one of the plurality of first semiconductor regions, in a depth direction of the semiconductor device.

4. The method of manufacturing according to claim 2, further comprising partially etching the trench mask to be of a thickness of 0.1 μm to 0.15 μm, after forming the plurality of gate insulating films but before forming the polycrystalline silicon layer.

5. A method of manufacturing a semiconductor device, the method comprising:
preparing a semiconductor substrate of a first conductivity type, the semiconductor substrate having a first main surface and a second main surface opposite to each other;
forming a first semiconductor layer of a second conductivity type at the first main surface of semiconductor substrate, the first semiconductor layer having a first surface and a second surface opposite to each other, the second surface facing the semiconductor substrate;
forming a nitride film at the first surface of the first semiconductor layer;
etching the nitride film, thereby forming a trench mask;
using the trench mask as a mask, thereby forming a plurality of trenches penetrating through the first semiconductor layer and reaching the semiconductor substrate;
leaving the trench mask as is and forming a plurality of gate insulating films along the first surface of the first semiconductor layer and bottoms and sidewalls of the plurality of trenches;
forming a polycrystalline silicon layer on the plurality of gate insulating films;
etching the polycrystalline silicon layer, thereby forming a plurality of gate electrodes;
selectively forming a plurality of first semiconductor regions of the first conductivity type in the first semiconductor layer, at the first surface of the first semiconductor layer;
forming a first electrode at the first surface of the first semiconductor layer and on the plurality of first semiconductor regions; and
forming a second electrode at the second main surface of the semiconductor substrate.
